(19) United States
(12) Patent Application Publication
(10) Pub. No.: US 2008/0258218 A1
(43) Pub. Date: Oct. 23, 2008

(54) SEMICONDUCTOR DEVICE AND METHOD OF MANUFACTURING THE SAME

(75) Inventors: Yusuke Morita, Amagasaki (JP); Yoshinobu Kimura, Tokyo (JP); Ryuta Tsuchiya, Tokyo (JP); Nobuyuki Sugii, Tokyo (JP); Shinichiro Kimura, Kunitachi (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 12/105,226

(22) Filed: Apr. 17, 2008

(30) Foreign Application Priority Data
Apr. 20, 2007 (JP) JP2007-112354

(51) Int. Cl. H01L 27/01

(52) U.S. Cl. 257/347; 257/E27.112

(57) ABSTRACT

A MIS transistor having an inclined stacked source/drain structure increased in speed is provided. The MIS transistor comprises: a gate electrode formed on a substrate; a first sidewall insulating film formed on the substrate and along a sidewall of the gate electrode; source/drain semiconductor regions formed on a main surface of the substrate and respectively having one edge positioned under the sidewall of the gate electrode; a first stacked layer formed on the source/drain semiconductor regions and in contact with the first sidewall insulating film; a second sidewall insulating film formed on the stacked layer and in contact with the first sidewall insulating film; and a second stacked layer formed on the first stacked layer and in contact with the second sidewall insulating layer.

### CROSS-REFERENCE TO RELATED APPLICATION

The present application claims priority from Japanese Patent Application No. JP 2007-112354 filed on Apr. 20, 2007, the content of which is hereby incorporated by reference into this application.

### TECHNICAL FIELD OF THE INVENTION

The present invention relates to a semiconductor device and a technique for manufacturing the semiconductor device. More particularly, the present invention relates to a technique effectively applied to a MIS (Metal Insulator Semiconductor) transistor having a stacked source/drain structure.

### BACKGROUND OF THE INVENTION

Higher speed, lower power consumption and multifunctionality have been required to large-scaled integrated circuits (LSIs) used in microcomputers for digital home appliances and personal computers, and analog high-frequency electronic components used in mobile communication terminals (e.g., transmission amplifier and reception integrated circuit). For example, as to MIS transistors represented by silicon (Si) field effect transistor (FET), it has been achieved to make the elements have higher performance (improvement in current driving, reduction in power consumption) by use of lithography technology, mainly, by shortening the gate length. However, as to MIS transistors having gate lengths equal to or smaller than 100 nm, using only the scaling technology incur problems of saturation (or decrease) of performance-improvement ratio and increase in power consumption due to the short-channel effect. Consequently, in fabrication of source/drain semiconductor regions, by designing profile of impurity density such as extension and halo structure, suppression of the short-channel effect has been promoted.

Forming shallow source/drain semiconductor regions is effective because it reduces an influence of electric field to the channel region and suppresses punch-through. Meanwhile, since the parasitic resistance of source/drain is increased, Si layers are stacked by using selective growth only to the source/drain part to reduce the parasitic resistance of source/drain.

To make an angle between a gate-side edge potion of the Si layer and a surface of a substrate smaller than 90 degrees in the case of growing the stacked Si layers, in other words, a method for reducing the parasitic capacitance between a gate and source/drain is disclosed in Japanese Patent Application Laid-Open Publication No. H8-298328 (Patent Document 1).

In addition, a method for suppressing punch-through by performing a high-density ion implantation under the gate and source/drain after forming a gap between the source/drain and gate is disclosed in Japanese Patent Application Laid-Open Publication No. 2001-15745 (Patent Document 2) and Japanese Patent Application Laid-Open Publication No. H11-74506 (Patent Document 3).

These Patent Document 1, Patent Document 2, and Patent Document 3 disclose uses of a facet surface formed in the selective growth in order to incline a surface of the gate-side edge portion of the stacked Si layers.

Hereinafter, a structure where a surface of the gate-side edge portion of the stacked layers have an angle to a main surface of the substrate (device formation surface) smaller than 90 degrees is called as an inclined stacked source/drain structure. Note that, the stacked source/drain is also called as elevated source/drain.

### SUMMARY OF THE INVENTION

The above-mentioned inclined stacked source/drain structure aiming for suppressing the short-channel effect and reducing the parasitic resistance and parasitic capacitance of source/drain has the following problems.

The inclination angle is limited to (113) plane and (111) plane having stable surface energy because a facet is formed by controlling conditions of the selective growth in the stacking growth. More particularly, in the case where the Si substrate has (001) orientation, the inclination angle of (113) facet is limited to 25 degrees, and that of (111) facet is limited to 55 degrees.

Further, a plurality of equivalent planes, for example, (331), (131) etc. in the case of (113) plane, and (−111), (11−1) etc. in the case of (111) plane may be formed at the same time in formation of the facet. In these cases, the inclined surface will not have a single plane, and thus variations in processed shape will occur. As a result, various parasitic capacitances will occur between the gate and source/drain. Moreover, in the case where ion implantation is performed between the gate and source/drain, the facet works as an ion implantation mask, and thus, ion implantation profile will be varied.

While the source/drain parasitic resistance is reduced when just stacking the source/drain, the parasitic capacitance will occur between the source/drain and gate. Therefore, since it is trade-off, optimization should be performed. For that reason, it is possible to construct an inclined stacked source/drain by, for example, using the facet of silicon. However, since the facet angle is a parameter, there will be a limit in the angle.

An object of the present invention is to provide a semiconductor device in which an inclination angle of an inclined stacked source/drain structure is freely controlled and a technique for manufacturing the semiconductor device.

The above and other objects and novel characteristics of the present invention will be apparent from the description of this specification and the accompanying drawings.

The typical ones of the inventions disclosed in this application will be briefly described as follows.

A semiconductor device according to the present invention comprises: a gate electrode on a semiconductor substrate; a first insulating film formed on the semiconductor substrate and along sidewalls of the gate electrode; source/drain semiconductor regions formed on a main surface of the semiconductor substrate and respectively having one edge under the sidewalls of the gate electrode; a first layer formed on the source/drain semiconductor regions and in contact with the first insulating film; a second insulating film formed on the first layer and along the first insulating film; and a second layer formed on the first layer and in contact with the second insulating film. Note that, the first and second insulating layers are sidewall insulating films to compose a spacer of the sidewall of the gate electrode, and the first and second insulating films are stacked layers to compose the source/drain electrodes.

Further, in a method of manufacturing a semiconductor device according to the present invention, first (a) a gate electrode of a MIS transistor is formed on a semiconductor substrate interposing a gate insulating film of the MIS transistor. Secondly, (b) a first insulating film is formed on the semiconductor substrate and along sidewalls of the gate electrode. Thirdly, (c) source/drain semiconductor regions of the MIS transistor, which are a main surface of the semiconductor substrate, are formed respectively having one edge under the sidewalls of the gate electrode. Fourthly, (d) a first layer is formed on the source/drain semiconductor regions and in contact with the first insulating film and composing the source/drain electrodes of the MIS transistor. Fifthly, (e) a second insulating film is formed on the first layer and along the first insulating film. Finally, (f) a second layer is formed on the first layer in contact with the first insulating film and composing the source/drain electrode.

The effects obtained by typical aspects of the present invention disclosed in the present application will be briefly described below.

According to the present invention, it is possible to arbitrarily adjust an inclination angle of an inclined stacked source/drain structure by determining thicknesses of a plurality of sidewall insulating films and thicknesses of a plurality of stacked layers composing the source/drain electrode. Therefore, the parasitic resistance of the source/drain is lowered by introducing the stacked structure, and further, the parasitic capacitance between source/drain is lowered by introducing the inclined shape, thereby providing a MIS transistor capable of high-speed operation.

The effects in the foregoing include not only speed improvement of a single transistor but also an achievement of a high-speed, high-withstand-voltage and low-power electronic element suitable for analog-digital-mixed circuits, for example.

### BRIEF DESCRIPTIONS OF THE DRAWINGS

FIG. 1 is a cross-sectional view of main parts showing an example of a semiconductor device according to a first embodiment;

FIG. 2 is a cross-sectional view of main parts showing the example of the semiconductor device according to the first embodiment in a manufacturing step;

FIG. 3 is a cross-sectional view of main parts showing the semiconductor device in a manufacturing step continued from FIG. 2;

FIG. 4 is a cross-sectional view of main parts showing the semiconductor device in a manufacturing step continued from FIG. 3;

FIG. 5 is a cross-sectional view of main parts showing the semiconductor device in a manufacturing step continued from FIG. 4;

FIG. 6 is a cross-sectional view of main parts showing the semiconductor device in a manufacturing step continued from FIG. 5;

FIG. 7 is a cross-sectional view of main parts showing the semiconductor device in a manufacturing step continued from FIG. 6;

FIG. 8 is a cross-sectional view of main parts showing the semiconductor device in a manufacturing step continued from FIG. 7;

FIG. 9 is a cross-sectional view of main parts showing the semiconductor device in a manufacturing step continued from FIG. 8;

FIG. 10 is a cross-sectional view of main parts showing the semiconductor device in a manufacturing step continued from FIG. 9;

FIG. 11 is a cross-sectional view of main parts showing the semiconductor device in a manufacturing step continued from FIG. 10;

FIG. 12 is a cross-sectional view of main parts showing the semiconductor device in a manufacturing step continued from FIG. 11;

FIG. 13 is a cross-sectional view of main parts showing the semiconductor device in a manufacturing step continued from FIG. 12;

FIG. 14 is a cross-sectional view of main parts showing the semiconductor device in a manufacturing step continued from FIG. 12;

FIG. 15 is a cross-sectional view of main parts showing another example of the semiconductor device according to the first embodiment;

FIG. 16 is a cross-sectional view of main parts showing an example of a semiconductor device according to a second embodiment;

FIG. 17 is a cross-sectional view of main parts showing the example of the semiconductor device according to the second embodiment in a manufacturing step;

FIG. 18 is a cross-sectional view of main parts showing the semiconductor device in a manufacturing step continued from FIG. 17;

FIG. 19 is a cross-sectional view of main parts showing the semiconductor device in a manufacturing step continued from FIG. 18;

FIG. 20 is a cross-sectional view of main parts showing the semiconductor device in a manufacturing step continued from FIG. 19;

FIG. 21 is a cross-sectional view of main parts showing the semiconductor device in a manufacturing step continued from FIG. 20;

FIG. 22 is a cross-sectional view of main parts showing the semiconductor device in a manufacturing step continued from FIG. 21;

FIG. 23 is a cross-sectional view of main parts showing the semiconductor device in a manufacturing step continued from FIG. 22;

FIG. 24 is a cross-sectional view of main parts showing the semiconductor device in a manufacturing step continued from FIG. 23;

FIG. 25 is a cross-sectional view of main parts showing the semiconductor device in a manufacturing step continued from FIG. 24;

FIG. 26 is a cross-sectional view of main parts showing the semiconductor device in a manufacturing step continued from FIG. 25;

FIG. 27 is a cross-sectional view of main parts showing the semiconductor device in a manufacturing step continued from FIG. 26;

FIG. 28 is a cross-sectional view of main parts showing the semiconductor device in a manufacturing step continued from FIG. 27;

FIG. 29 is a cross-sectional view of main parts showing the semiconductor device in a manufacturing step continued from FIG. 27; and

FIG. 30 is a cross-sectional view of main parts showing another example of the semiconductor device according to the second embodiment.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

### First Embodiment

First, a structure of a semiconductor device comprising a MIS transistor according to a first embodiment of the present invention will be described.

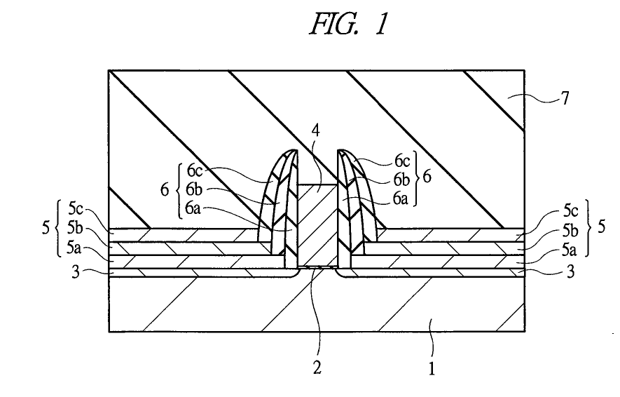

As shown in FIG. 1, a semiconductor substrate (hereinafter, it is referred to just as “substrate”) 1 formed of a silicon single crystal substrate having a first conductive type (e.g., p type) has a main surface (element formation surface). And, on the entire surface or part of the main surface, source/drain semiconductor regions 3 having a second conductive type opposite to the first conductive type (n type) are provided so as to face each other having a predetermined gap therebetween. In addition, a gate insulating film 2 is provided on a surface of the substrate 1 and between the source/drain semiconductor regions 3, and a gate electrode 4 is provided on the gate insulating film 2.

In other words, the gate electrode 4 is formed on the substrate 1 interposing the gate insulating film 2, and the source/drain regions 3 are formed on the main surface of the substrate 1 and respectively having one edge positioned under sidewalls of the gate electrode 4.

Further, on the substrate 1, a stacked layer (three stacked layers 5a, 5b, 5c in FIG. 1) comprising at least two or more layers of a semiconductor layer having a low resistance and the second conductive type and formed along a surface of the gate electrode 4 and the source/drain regions 3 is provided. These stacked layers 5a to 5c compose a source/drain electrode 5. Still further, on the substrate 1, sidewall insulating films (sidewall insulating films 6a, 6b, 6c) are provided comprising two or more layers and interposed between a part where the source/drain electrode 5 and the gate electrode 4 are most adjacent. These sidewall insulating films 6a to 6c compose a spacer 6. Moreover, an interlayer insulating film 7 is provided on the substrate 1 (stacked layer 5c) so as to cover the gate electrode 4.

In other words, the sidewall insulating film 6a is formed on the substrate 1 and along sidewalls of the gate electrode 4, and the stacked layer 5a is formed on the source/drain semiconductor regions 3 in contact with the sidewall insulating film 6a and composing the source/drain electrode 5. Further, the sidewall insulating film 6b is formed on the stacked layer 5a and along the sidewall insulating film 6a, and the stacked layer 5b is formed on the stacked layer 5a in contact with the sidewall insulating film 6a and composing the source/drain electrodes 5. Still further, the sidewall insulating film 6c is formed along the sidewall insulating film 6b on the stacked layer 5b, and the stacked layer 5c is formed on the stacked layer 5b in contact with the sidewall insulating film 6a and composing the source/drain electrode 5.

As shown in FIG. 1, an inclined stacked source/drain structure of the MIS transistor includes sidewall insulating films 6a to 6c respectively provided between the gate electrode 4 and the stacked layers 5a to 5c, and the distance from the gate electrode 4 gets longer with respect to the upper layer. In the present embodiment 1, the source/drain electrode 5 at the gate electrode 4 side has a step-like shape. Alternatively, the shape has a slope having an angle smaller than 90 degrees to the main surface of the substrate 1, and it is possible to arbitrarily adjust an inclination angle of the inclined stacked source/drain structure by determining thicknesses of the sidewall insulating films and thicknesses of the plurality of stacked layers 5a to 5c composing the source/drain electrode 5.

By introducing the stacked structure in this manner, parasitic resistances of the source/drain composed of the source/drain semiconductor regions 3 and the source/drain electrodes 5 become lower as compared with the case not having a stacked structure. Further, by introducing the inclined type, parasitic capacitances between the gate electrode 4 and the source/drain electrode 5 becomes lower as compared with the case of not inclined type. Since parasitic capacitances are lowered, the MIS transistor can be operated in a high speed.

In addition, as compared with the case of constructing an inclined stacked source/drain having a constant angle by using a facet of silicon (e.g., above-mentioned Patent Documents 1 to 3), the present first embodiment is capable of arbitrarily adjusting the inclination angle of the inclined stacked source/drain structure by thicknesses of the sidewall insulating films 6a to 6c and thicknesses of the plurality of stacked layers 5a to 5c, thereby making the MIS transistor most suitable for high-speed operation.

Further, since the spacer 6 comprises the plurality of sidewall insulating films, it is possible to make dielectric constants of the respective sidewall insulating films different. For example, it is preferable when silicon oxide (SiO₂) is applied to the sidewall insulating film 6a and silicon nitride is applied to the sidewall insulating films 6b, 6c so that the dielectric constant of the sidewall insulating film 6a is higher than the outer sidewall insulating films 6b, 6c, because the driving current of the transistor can be increased. In the present first embodiment, it is preferable to have the outer sidewall insulating film having same or lower dielectric constant than inner sidewall insulating film, so that the driving current can be increased.

Still further, in the present first embodiment, while the MIS transistor has had the source/drain semiconductor regions 3 of n-type as an n-channel type MIS transistor, it can also have the source/drain semiconductor 3 of p-type as a p-channel type MIS transistor. Moreover, by these n-channel type MIS transistor and p-channel type MIS transistor adjacent to each other, also a CMIS (Complementary Metal Insulator Semiconductor) element can be formed.

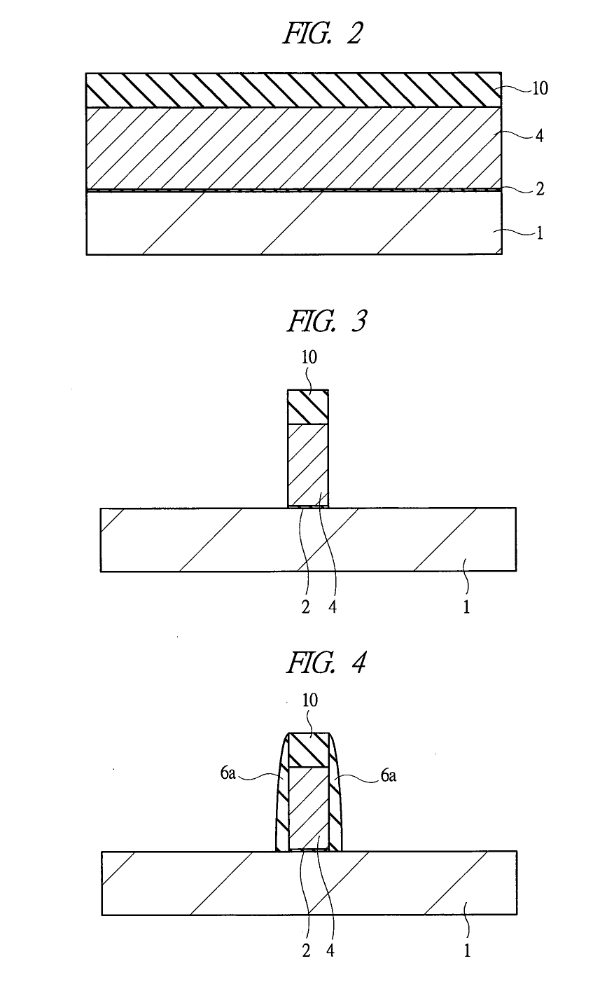

Next, a method of manufacturing the semiconductor device comprising the MIS transistor according to the first embodiment of the present invention will be described with reference to FIG. 2 to FIG. 14.

First, as shown in FIG. 2, after a well and an device isolation region (not shown) are formed on the main surface (element formation surface) of the substrate 1 formed by, for example, a p-type single silicon crystal substrate, the gate insulating film 2, gate electrode 4, and cap 10 are deposited. And then, as shown in FIG. 3, the gate insulating film 2 on the substrate 1, the gate electrode 4 on the gate insulating film 2, and the cap 10 on the gate electrode 4 are patterned (formed).

More particularly, as shown in FIG. 2, after the well and the device isolation region (not shown) are formed on the main surface (element formation surface) of the substrate 1 formed by, for example, a p-type single silicon crystal substrate, the gate insulating film 2 (e.g., SiO₂, SiOₓN_{y}, SiₓN_{y}, Ta₂O₅, TiO₂, Al₂O₃, etc.) is formed by a well-known film-formation method. Next, the gate electrode film 4 formed of, for example, a highly-doped polycrystalline silicon is formed on the gate insulating film 2 by a well-known film-formation method, and the cap 10 formed of, for example, Si₃N₄ is deposited on the gate electrode film by a well-known film-formation method. The cap 10 is provided to prevent an impurity to be implanted in the gate electrode film 4 when implanting the impurity to the surface of the substrate 1 in an upcoming step. Next, as shown in FIG. 3, by using a well-known lithography, the cap 10, gate electrode film 4, and gate insulating film 2 are patterned, thereby making the gate electrode 4. In this manner, the gate electrode 4 of the MIS transistor is formed on the substrate 1 interposing the gate insulating film 2 of the MIS transistor.

Subsequently, as shown in FIG. 4, a silicon oxide film is deposited on the substrate 1 so as to cover the gate electrode 4, and the sidewall insulating film 6a is formed along the gate electrode 4 by etching. More particularly, after a SiO₂ film (e.g., film thickness is 1 to 10 nm) is formed on the entire surface of the substrate by using a well-known low-pressure chemical vapor deposition, the SiO₂ film is etched by reactive etching, so that the first sidewall insulating film 6a is formed along the gate electrode 4. In this manner, the sidewall insulating film 6a is formed on the substrate 1 and along the gate electrode 4.

Subsequently, as shown in FIG. 5, the source/drain semiconductor regions 3 are formed by implanting an impurity to the main surface of the substrate 1. More particularly, as using the cap 10 and the sidewall insulating film 6a as a mask, an n-type impurity (e.g., arsenic or phosphorus) is implanted by a well-known ion implantation 12 (e.g., acceleration voltage 5 keV, 10¹⁵ cm⁻²), and a well-known activation annealing (e.g., RTA (Rapid Thermal Annealing) at 1000° C. for 1 second) is performed, thereby forming the source/drain semiconductor regions 3. In this manner, the source/drain semiconductor regions 3 of the MIS transistor, which are the main surface of the substrate 1 and respectively having one edge positioned under the sidewalls of the gate electrode 4 are formed.

Subsequently, the halo regions (not shown) are formed by performing an oblique ion implantation 13 of boron (e.g., 5 keV, 10¹³ cm⁻²) and a well-known activation annealing (e.g., RTA at 1000° C. for 1 second).

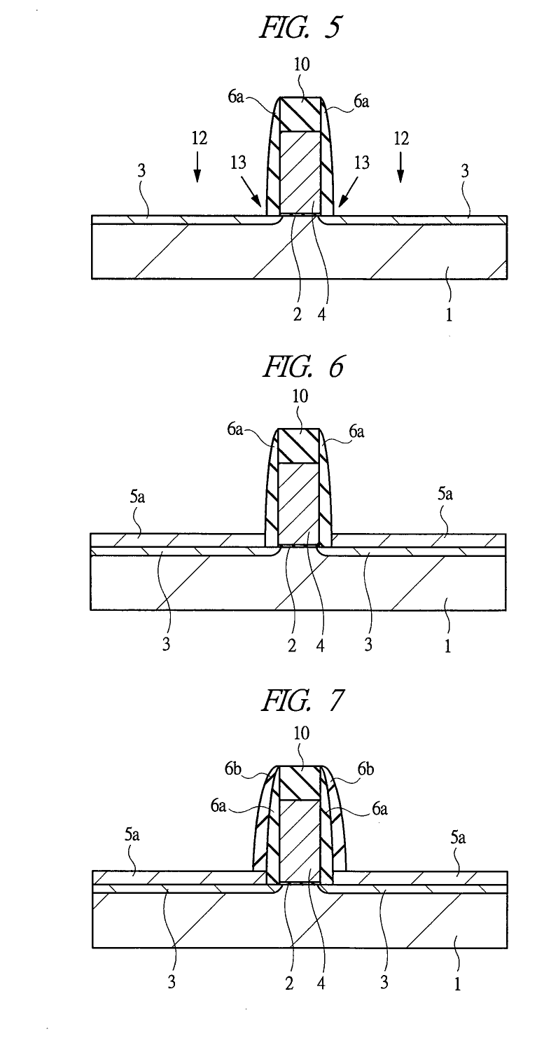

Subsequently, as shown in FIG. 6, the stacked layer 5a including silicon is formed on the source/drain semiconductor regions 3 by selective epitaxial growth. More particularly, the first stacked layer 5a formed of a silicon layer (e.g., film thickness is 1 to 10 nm) is formed on the source/drain semiconductor regions 3 by means of selective epitaxial growth (e.g., a well-known low-pressure chemical vapor deposition using dichlorosilane and hydrochloric gas). In this manner, the stacked layer 5a composing the source/drain electrode of the MIS transistor is formed on the source/drain semiconductor regions 3 and in contact with the sidewall insulating film 6a. At this time, while an edge of the stacked layer 5a at the gate electrode 4 side may have a facet formed thereto according to conditions of the crystal growth, it is not a matter whether a facet is formed or not in the present invention.

Subsequently, as shown in FIG. 7, a silicon oxide film is deposited on the substrate 1 so as to cover the gate electrode 4 and the sidewall insulating film 6a, and the sidewall insulating film 6b is formed along the sidewall insulating film 6a by etching. After forming a SiO₂ film (e.g., film thickness is 1 to 10 nm) on the entire surface of the substrate 1 by means of a well-known low-pressure chemical vapor deposition, the SiO₂ film is etched by means of a well-known reactive ion etching, thereby forming the sidewall insulating film 6b. In this manner, the sidewall insulating film 6b is formed on the stacked layer 5a and along the sidewall insulating film 6a. Note that, while a silicon oxide film has been applied to the sidewall insulating film 6b, a silicon nitride film or an insulating film having a lower dielectric constant than silicon oxide can be used.

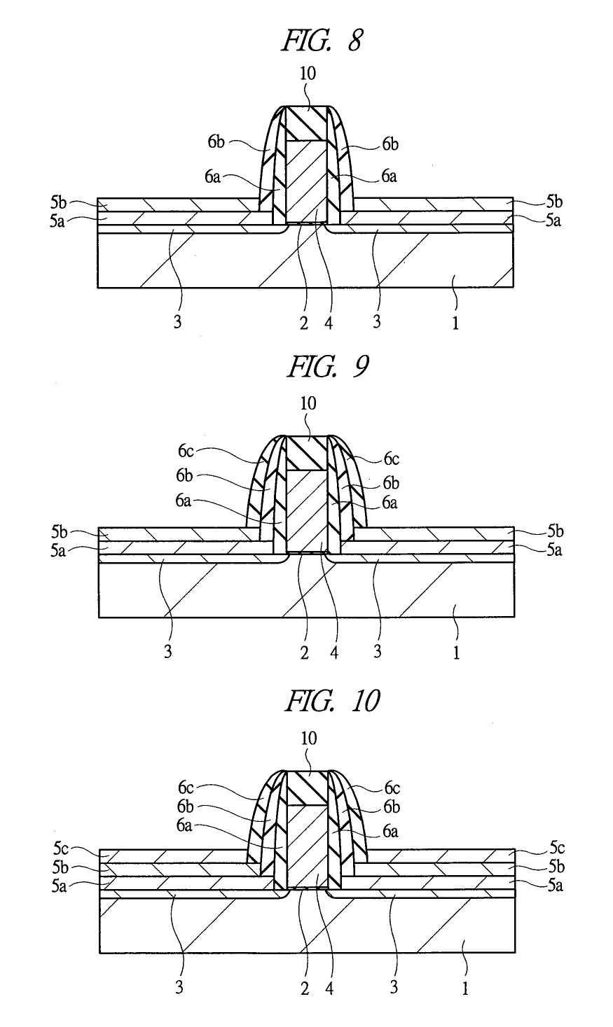

Subsequently, as shown in FIG. 8, the stacked layer 5b including silicon is formed on the stacked layer 5a by selective epitaxial growth. More particularly, by means of selective epitaxial growth (e.g., a well-known low-pressure chemical vapor deposition using dichlorosilane and hydrochloric gas), the second stacked layer 5b formed of a silicon layer is formed on the source/drain semiconductor regions 3 (stacked layer 5a). In this manner, the stacked layer 5b is formed on the stacked layer 5a in contact with the sidewall insulating film 6a and composing the source/drain electrodes. At this time, while an edge of the stacked layer 5b at the gate electrode 4 side may have a facet formed thereto according to conditions of the crystal growth, in the present invention, it is not a matter whether a facet is formed or not.

Subsequently, as needed, the formation of sidewall insulating film and the formation of stacked layer are repeated to form the third (cf., FIG. 10), a fourth, . . . , an n-th sidewall insulating films and the third (cf., FIG. 10), a fourth, . . . , an n-th stacked layer may be formed. In this manner, the source/drain electrodes 5 of the MIS transistor comprising two or more stacked layers are formed. Note that, “n” is a positive integer, and the case where n is 3 is described in the present first embodiment.

Subsequently, after removing the cap 10 on the gate electrode 4 by hot phosphoric acid as shown in FIG. 11, an ion implantation 14 (e.g., 10 keV, 10¹⁵ cm⁻²,) of arsenic (As) to the source/drain semiconductor region 3 as shown in FIG. 12 and an activation annealing (e.g., RTA at 1000° C. for 1 second) are performed.

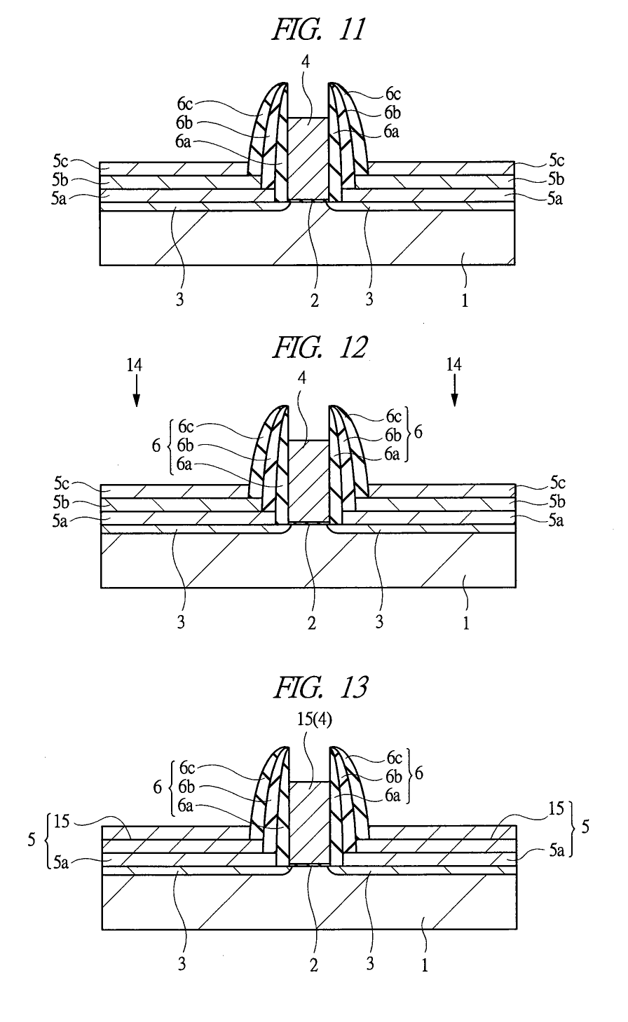

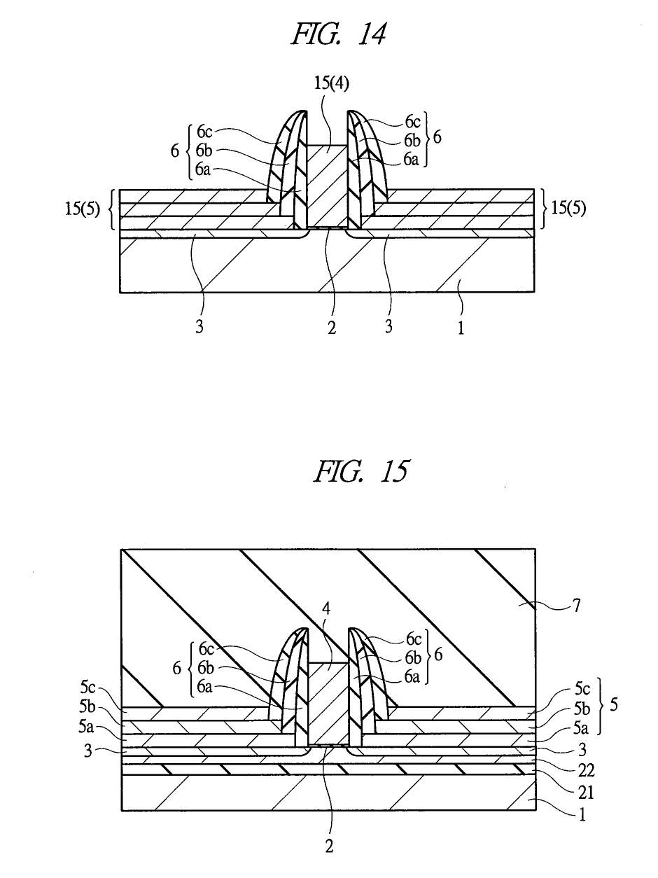

Subsequently, as needed, a metal silicide film 15 (e.g., a compound of silicon and a metal such as cobalt, nickel, platinum, tungsten, molybdenum) may be formed to the gate electrode 4, and source/drain electrodes 5 by silicide technique (cf. FIG. 13, FIG. 14).

The metal silicide film 15 can be formed on a part of or entire of the stacked layer. For example, as shown in FIG. 13, part of the stacked layers Sb, 5c are silicided. Further, for example, as shown in FIG. 14, all of the stacked layers are silicided. By siliciding the stacked layers, an ohmic connection can be obtained with a contact formed in an upcoming step.

Subsequently, the interlayer insulating film 7, the contact, a wiring are formed, thereby finishing the high-speed MIS transistor according to the present first embodiment.

In the present first embodiment, while SiO₂ has been used for the material of the sidewall insulating films 6a to 6c, other insulator materials (e.g., SiOₓN_{y}, SiₓN_{y}, Ta₂O₅, Al₂, O₃, etc.) can be used.

Further, instead of composing all the stacked layers 5a to 5c by silicon layers, it is possible to use a silicon germanium layer to the stacked layer 5a as the lowermost layer, and a silicon layer to the stacked layers 5b, 5c as the upper layers, respectively. The silicon germanium layer is formed by a selective epitaxial growth (e.g., a well-known low-pressure chemical vapor deposition using dichlorosilane, monogermane and hydrochloric gas). In this manner, the lowermost stacked layer 5a comprises a semiconductor layer having a work function between that of the source/drain regions 3 (silicon) and that of the upper stacked layer 5b (metal or metal silicide). Therefore, when the silicon layer is silicided, an interface resistance between the silicon germanium layer and the silicide layer is lowered than that between the silicon layer and the silicide layer. As a result, the parasitic resistance of source/drain is lowered, and thus it is preferable.

Still further, in the present first embodiment, while the case applying a single crystal silicon substrate to the substrate 1 has been described, as another example, instead of a single crystal silicon substrate, an SOI (Silicon on Insulator) substrate can be used as shown in FIG. 15. In this case, the source/drain semiconductor regions 3 are provided to an SOI layer 22 of the SOI substrate.

Since the MIS transistor using an SOI substrate is low-power, it is preferable. And, it is preferable when an SOI substrate having the SOI layer 22 with a thickness equal to or smaller than 100 nm is used because sub-threshold characteristics are improved and the MIS transistor operates at a high speed. In addition, when an SOI substrate having a buried oxide film 21 with a thickness equal to or lower than 10 nm is used, a four-terminal MIS transistor using back-bias control can be formed. The four-terminal field effect transistor is preferable because it can control off-leakage current reduction and on-current improvement, and further, a circuit for suppressing variations of threshold voltage can be formed.

Further, in the present first embodiment, while an embodiment of an n-channel type MIS transistor has been described, as to a p-channel type MIS transistor, it can be formed by changing various steps for reversed conductive type.

The most significant feature of the cross-sectional shape of the MIS transistor formed according to the present first embodiment is the shape of the source/drain electrode at the gate electrode side having a step-like shape or a shape inclined by an angle smaller than 90 degrees to the main surface of the substrate. To make such a shape of the source/drain electrode, it is only necessary to select respective thicknesses of the plurality of sidewall insulating films composing the spacer and the plurality of stacked layers composing the source/drain electrode. In other words, by selecting each thickness of each sidewall insulating film and each stacked layer, it is possible to arbitrarily adjust the inclination angle of the inclined stacked source/drain structure, thereby making the MIS transistor most suitable for high-speed operation.

### Second Embodiment

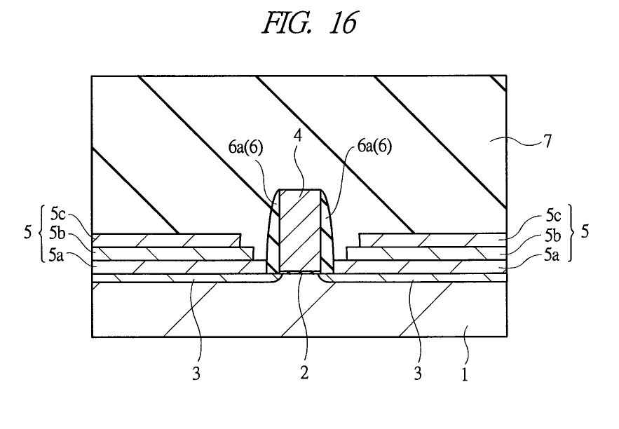

In the MIS transistor of the first embodiment described above (cf. FIG. 1), the spacer 6 has been composed of three sidewall insulating films 6a to 6c. In a present second embodiment, as shown in FIG. 16, a semiconductor device comprising a MIS transistor in which the spacer 6 is composed of one layer of the sidewall insulating film 6a will be described. Note that, other configurations are same with those of the first embodiment.

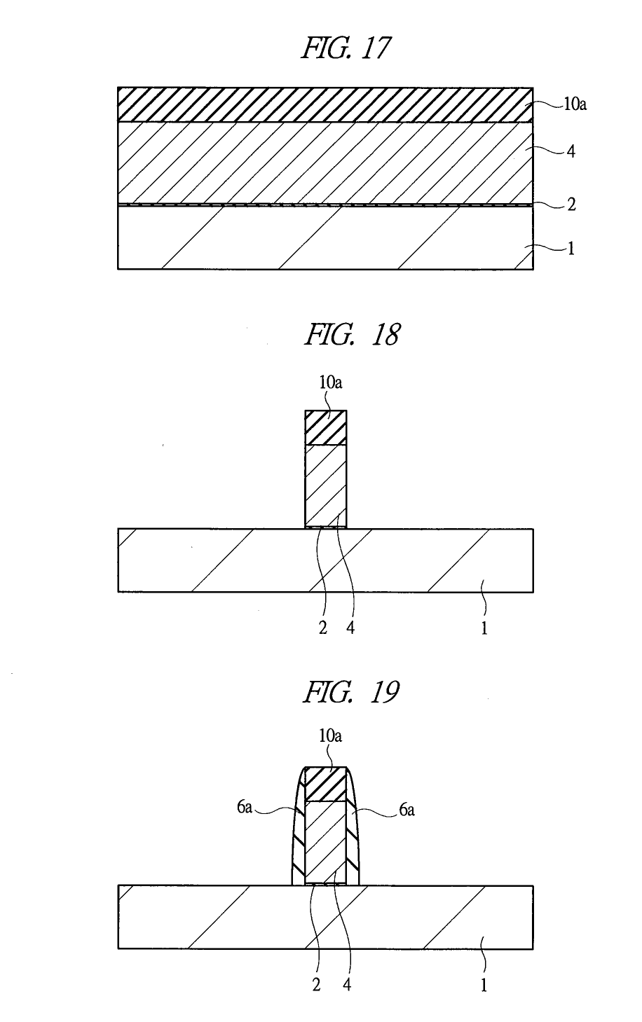

A method of manufacturing the semiconductor device comprising the MIS transistor according to the second embodiment will be described with reference to FIG. 17 to FIG. 29.

First, as shown in FIG. 17, after forming a well and a device isolation region (not shown) to the surface of the substrate 1 formed of a p-type single crystal silicon substrate, the gate insulating film 2 (e.g., SiO₂, SiOₓN_{y}, SiₓN_{y}, Ta₂O₅, TiO₂, Al₂O₃, etc.) is formed on the substrate 1 by a well-known film-formation method. Next, the gate electrode film 4 formed of, for example, a highly-doped polycrystalline silicon is formed on the gate insulating film 2 by a well-known film-formation method, and a cap 10a formed of a silicon oxide (SiO₂) film is deposited on the gate electrode film 4 by a well-known film-formation method.

Subsequently, the gate electrode film 4 is patterned by using a well-known lithography, thereby forming the gate electrode 4 as shown in FIG. 18.

Subsequently, after forming a silicon oxide (SiO₂) film (e.g., film thickness is 1 to 10 nm) on the entire surface of the substrate 1 by using a well-known low-pressure chemical vapor deposition, the SiO₂ film is etched by a reactive ion etching, thereby forming the first sidewall insulating film 6a on the gate sidewalls as shown in FIG. 19.

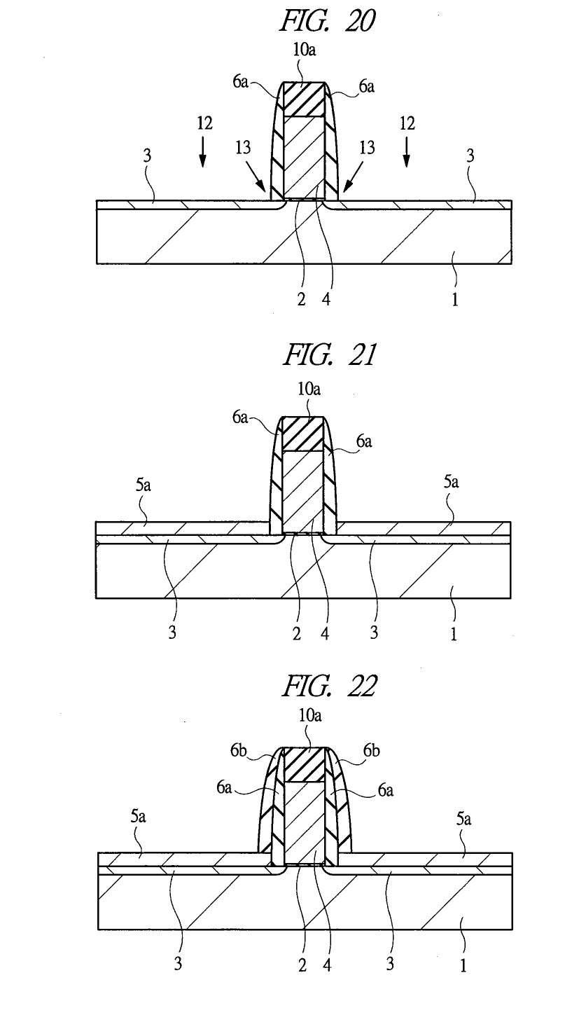

Subsequently, as shown in FIG. 20, by using the cap 10a and sidewall insulating film 6a as a mask, the source/drain semiconductor regions (extensions) 3 are formed by performing the well-known ion implantation 12 (e.g., acceleration voltage 5 keV, 10¹⁵ nm⁻²) of arsenic (As) and a well-known activation annealing (e.g., RTA at 1000° C. for one second). In addition, similarly to the first embodiment described above, a halo region (not shown) may be formed by the ion implantation 13 of boron.

Subsequently, as shown in FIG. 21, the first stacked layer 5a (e.g., film thickness is 1 to 10 nm) formed of a silicon layer is formed on the source/drain semiconductor regions 3 by using a selective epitaxial growth (e.g., a well-known low-pressure chemical vapor deposition using dichlorosilane and hydrochloric gas). At this time, while an edge of the stacked layer 5a at the gate side may have a facet formed thereto according to conditions of the crystal growth, it is not a matter whether a facet is formed or not in the present invention.

Subsequently, after forming a silicon nitride (SiN) film (e.g., film thickness is 1 to 10 nm) on the entire surface of the substrate 1 by using a well-known low-pressure chemical vapor deposition, the SiN film is etched by using a well-known reactive ion etching, thereby forming the second sidewall insulating film 6b on the gate sidewalls.

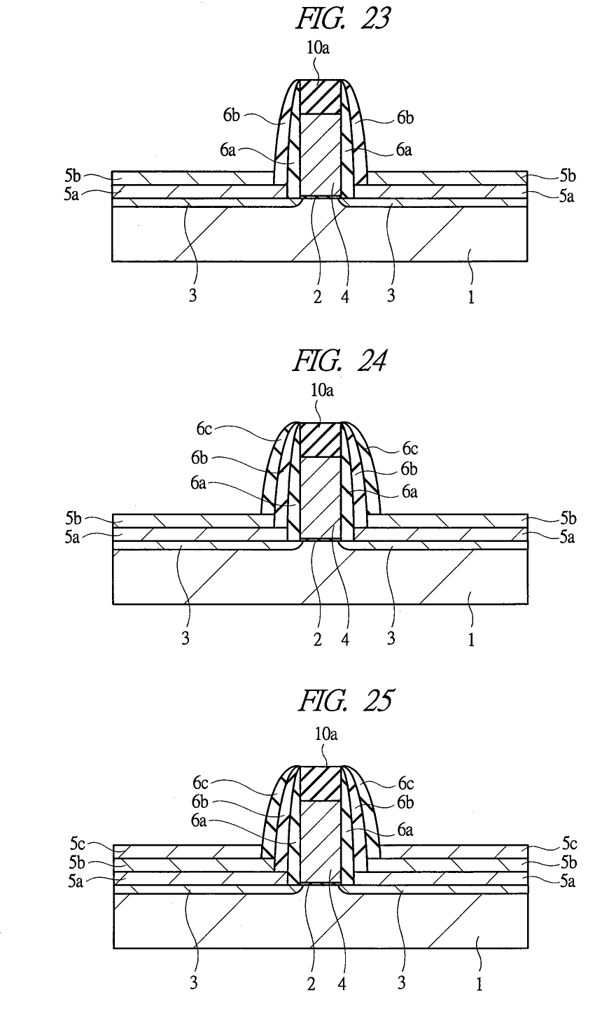

Subsequently, as shown in FIG. 23, the second stacked layer 5b formed of a silicon layer is formed on the stacked layer 5a (source/drain semiconductor region 3) by using a selective epitaxial growth (e.g., a well-known low-pressure chemical vapor deposition using dichlorosilane and hydrochloric gas). At this time, while an edge of the stacked layer 5b at the gate side may have a facet formed thereto according to conditions of the crystal growth, it is not a matter whether a facet is formed or not in the present invention.

Subsequently, as needed, the formation of the sidewall insulating film formed of a silicon nitride film and the formation of the stacked layer formed of a silicon layer described above can be repeated to form the third (shown by 6c in FIG. 24), a fourth, . . . , an n-th sidewall insulating films, and the third (shown by 5c in FIG. 24), a fourth, . . . , an n-th stacked layers. Note that, “n” is a positive integer, and the case where n is 3 is described in the present second embodiment.

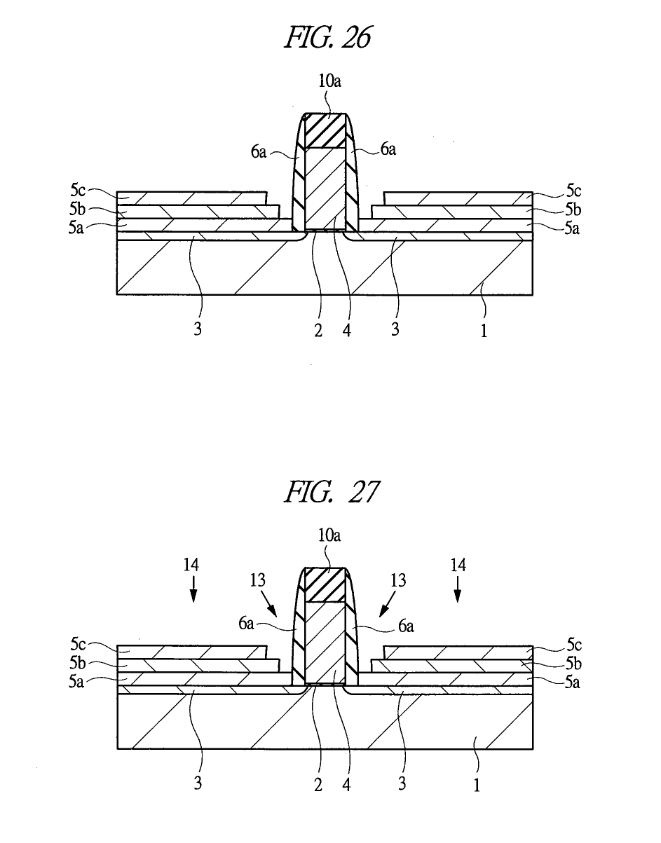

Subsequently, as shown in FIG. 26, with leaving the first sidewall insulating film 6a formed of silicon oxide (SiO₂), the second to n-th sidewall insulating films formed of silicon nitride (SiN) (sidewall insulating films 6b, 6c in the present second embodiment) are removed by hot phosphoric acid. At this time, since the cap 10a is formed of a silicon oxide film, it is left unremoved.

Subsequently, as shown in FIG. 27, the ion implantation 14 (e.g., acceleration voltage 10 keV, 10¹⁵ nm⁻²) of arsenic (As) to the source/drain semiconductor regions 3 and an activation annealing (e.g., RTA at 1000° C. for one second) are performed.

After that, a halo region (not shown) can be formed at one edge of the respective source/drain semiconductor regions 3 by implanting an impurity to the main surface of the substrate 1 under the gate electrode 4 from an oblique direction. More particularly, after performing the well-known oblique ion implantation 13 (e.g., acceleration voltage 5 keV, 10¹³ nm⁻²) of boron, a well-known activation annealing (e.g., RTA at 1000° C. for one second) is performed, thereby forming halo regions (not shown). To form halo regions can reduce variations than the halo regions formed in the step described with reference to FIG. 20. It is because the angle of the ion implantation of an impurity can be determined by the plurality of stacked layers 5a to 5c composing the source/drain electrode. In other words, when taking the stacked layers 5a to 5c as one (source/drain electrode), the shape of the source/drain electrode at the gate electrode 4 side has an inclination smaller than 90 degrees to the main surface of the substrate 1. Therefore, the angle to implant an impurity for forming halo regions can be determined.

For example, in the case where the inclined stacked source/drain having a constant angle is structured by using a silicon facet (e.g., above-mentioned Patent Documents 1 to 3), there will be some cases where a plurality of planes are formed at the same time, for example, in the case of (113) plane, (311), (131), etc., and in the case of (111) plane, (−111), (11-1), etc. In this case, when an ion implantation is performed between the gate and the source/drain, the facet works as a mask of implantation, and thus the ion implantation profile may be varied. However, in the present second embodiment, since the angle to implant the impurity is determined according to the shape of the source/drain electrode at the gate electrode 4 side, variations in the ion implantation profile can be prevented. Further, while the inclination angle is limited when a facet is used, the inclination angle can be controlled freely in the present second embodiment, and thus halo regions can be formed at arbitral positions.

Subsequently, the cap 10a formed of silicon oxide on the gate electrode 4 is removed by a well-known dry etching (anisotropic etching). At this time, the first sidewall insulating film 6a formed of silicon oxide is partly etched at the same time, and it should be careful not to over etch the sidewall insulating film 6a.

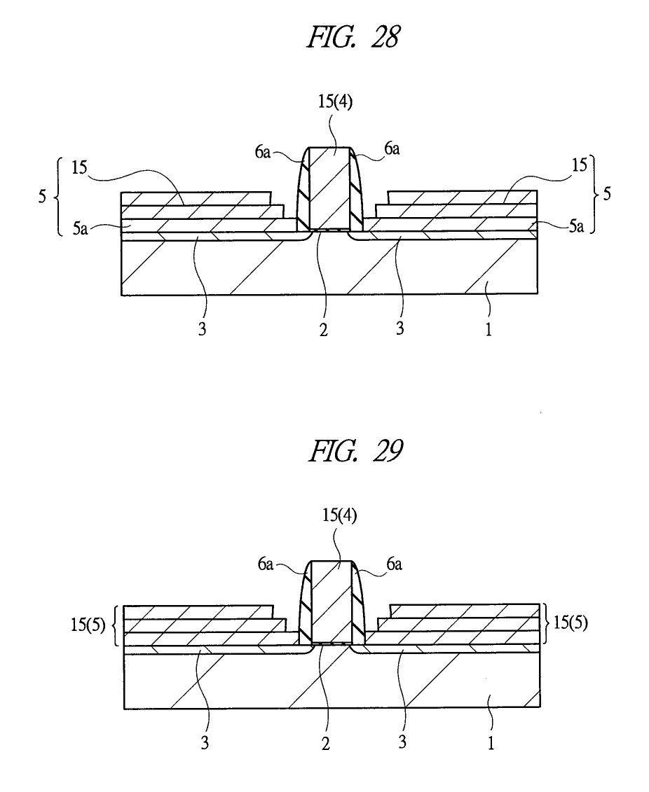

Subsequently, as needed, as shown in FIG. 28 and FIG. 29, the metal silicide film 15 (e.g., a chemical compound of silicon and a metal such as cobalt, nickel, platinum, tungsten, and molybdenum) may be formed to the gate and the source/drain by salicide technology. The metal silicide film 15 is formed on a part (FIG. 28) or all (FIG. 29) of the stacked layers.

Subsequently, by forming the interlayer insulating film 7, a contact, and a wiring etc., the high-speed MIS transistor according to the present second embodiment is formed. For example, a silicon oxide (SiO₂) film is deposited on the entire surface of the substrate 1 by CVD, thereby forming the interlayer insulating film 7. In the present second embodiment, the interlayer insulating film 7 is formed also to a region (space) between the sidewall insulating film 6a (gate electrode 4) and the source/drain electrode 5 formed by removing the sidewall insulating films 6b, 6c so as to make the silicon oxide (SiO₂) film buried in the space. This space is not necessary to be wholly buried by the interlayer insulating film 7, and parasitic capacitances of the gate electrode 4 and the source/drain electrodes 5 can be lowered by providing a void (air: relative permittivity 1).

In addition, instead of the stacked layer described above, a silicon-germanium mixed crystal can be used for the first stacked layer 5a, and a silicon layer can be used for the second stacked layer 5b. The silicon germanium layer (stacked layer 5a) is formed by using a selective epitaxial growth (e.g., a well-known low-pressure chemical vapor deposition using dichlorosilane, monogermane and hydrochloric gas). When the silicon layer (stacked layer 5b) is silicided, the interface resistance between the silicon germanium layer and silicide layer becomes lower than that between silicon layer and the silicide layer, thereby lowering the source/drain parasitic resistance as a result, and thus it is preferable.

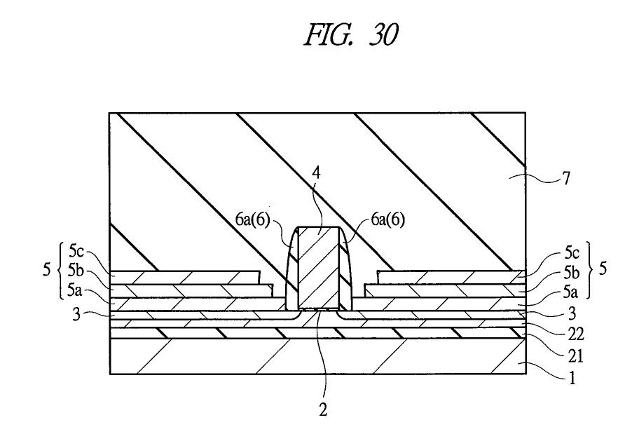

Further, in the present second embodiment, while it has been described about the case where a single crystal silicon substrate is applied to the substrate 1, as shown in FIG. 30, an SOI substrate can be used instead of the single crystal silicon substrate. The MIS transistor using an SOI substrate is low-energy and thus it is preferable. And, when an SOI substrate having the SOI layer 22 with a thickness equal to or smaller than 100 nm, the operation becomes high-speed because subthreshold characteristics are improved, and thus it is preferable. In addition, when an SOI substrate having the buried oxide film 21 with a thickness equal to or smaller than 10 nm is used, a four-terminal MIS transistor using back-bias control can be formed. The four-terminal MIS transistor can control reduction of off-leakage current and improvement of on-current and also compose a circuit for suppressing variations in the threshold voltage, and thus it is preferable.

More over, while an embodiment of an n-channel type MIS transistor has been described in the present second embodiment, as to a p-channel type MIS transistor, it is possible to form it by changing various steps for reversed conductive type.

The most significant feature of the cross-sectional shape of the MIS transistor formed according to the present first embodiment is the shape of the source/drain electrode at the gate electrode side having a step-like shape or a shape inclined by an angle smaller than 90 degrees to the main surface of the substrate. To make such a shape of the source/drain electrode, it is only necessary to select respective thicknesses of the plurality of sidewall insulating films composing the spacer and the plurality of stacked layers composing the source/drain electrode. In other words, by selecting each thickness of each sidewall insulating film and each stacked layer, it is possible to arbitrarily adjust the inclination angle of the inclined stacked source/drain structure, thereby making the MIS transistor most suitable for high-speed operation.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, while the gate electrode of the MIS transistor has been described to be formed of a highly-doped polycrystalline silicon (metal silicide) in the embodiments described above, the gate electrode may be formed of a metal.

The present invention is widely applicable for manufacturing fields that manufacture semiconductor devices.

1. A semiconductor device comprising a MIS transistor formed on a main surface of a semiconductor substrate, the semiconductor device including:
a gate electrode of the MIS transistor formed on the semiconductor substrate interposing a gate insulating film of the MIS transistor;
a first insulating film formed on the semiconductor substrate and along sidewalls of the gate electrode;
source/drain semiconductor regions of the MIS transistor formed on the main surface of the semiconductor substrate and respectively having one edge under the sidewalls of the gate electrode;
a first layer formed on the source/drain semiconductor regions in contact with the first insulating layer and composing source/drain electrodes of the MIS transistor;
a second insulating film formed on the first layer and along the first insulating film; and
a second layer formed on the first layer formed in contact with the second insulating film and composing the source/drain electrodes.

2. A semiconductor device comprising a MIS transistor formed on a main surface of a semiconductor substrate, the semiconductor device including:
a gate electrode of the MIS transistor formed on the semiconductor substrate interposing a gate insulating film of the MIS transistor;
source/drain regions formed on the main surface of the semiconductor substrate and respectively having one edge under sidewalls of the gate electrode;
a first layer formed on the source/drain semiconductor regions without contacting the gate electrode and composing source/drain electrodes of the MIS transistor; and
a second layer formed on the first layer without contacting the gate electrode and with a distance from the gate electrode farther than that from the first layer, and composing the source/drain electrodes.

3. The semiconductor device according to claim 1,
wherein the source/drain semiconductor regions at the gate electrode side have a step-like shape.

4. The semiconductor device according to claim 1,
wherein the source/drain semiconductor regions at the gate electrode side have a slope-like shape.

5. The semiconductor device according to claim 2,
wherein the second layer is formed of a metal or a silicide.

6. The semiconductor device according to claim 5,
wherein the first layer is formed of a semiconductor layer having a work function between a work function of the source/drain semiconductor regions and a work function of the silicide.

7. The semiconductor device according to claim 1,
wherein the semiconductor substrate is formed of a single crystal silicon substrate, and
wherein the first layer is a semiconductor layer formed of silicon or a silicon-germanium mixed crystal.

8. The semiconductor device according to claim 1,
wherein the semiconductor substrate is formed of an SOI substrate,
wherein the source/drain semiconductor regions are formed in an SOI layer of the SOI substrate, and
wherein a thickness of the SOI layer is equal to or smaller than 100 nm.

9. The semiconductor device according to claim 1,
wherein the semiconductor substrate is formed of an SOI substrate, and
wherein a thickness of a buried oxide film of the SOI substrate is equal to or smaller than 10 nm.

10. The semiconductor device according to claim 1,
wherein a dielectric constant of the first insulating layer is higher than that of the second insulating layer.

11-20. (canceled)
